(19) United States
(12) Patent Application Publication
(10) Pub. No.: US 2008/0301346 A1
(43) Pub. Date: Dec. 4, 2008

(54) MOTHER BOARD MODULE AND PERSONAL COMPUTER HOST USING THE SAME

(75) Inventors: Chih-Wei Wu, Taipei Hsien (TW); Chia-Yi Chang, Taipei Hsien (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: DFI, INC., Taipei Hsien (TW)

(21) Appl. No.: 12/108,517

(22) Filed: Apr. 24, 2008

(30) Foreign Application Priority Data
Jun. 1, 2007 (TW) 96209071

(51) Int. Cl. H05K 7/10

(52) U.S. Cl. 710/301

(57) ABSTRACT

A mother board module suitable for being disposed in a housing of a personal computer (PC) host is provided. The housing has expansion port openings at a rear wall of the housing. The mother board module includes a mother board, a sound card and a signal transmission cable. The mother board includes a circuit board and interface card slots. The interface card slots are juxtaposed on the circuit board and disposed corresponding to the expansion port openings respectively. The sound card has a fixing plate and audio jacks disposed thereon. Each of the audio jacks has a plug-in hole. The fixing plate is suitable for being removably fixed on one of the expansion port openings, which exposes the plug-in holes of the audio jacks beyond the rear wall. Two ends of the signal transmission cable are connected with the sound card and the circuit board respectively.

### CROSS-REFERENCE TO RELATED APPLICATION

This application claims the priority benefit of Taiwan application serial no. 96209071, filed. Jun. 1, 2007. The entirety of the above-mentioned patent application is hereby incorporated by reference herein and made a part of this specification.

### BACKGROUND OF THE INVENTION

1. Field of Invention

The present invention relates to an electronic element module and a computer host using the same. More particularly, the present invention relates to a mother board module and a personal computer host using the same.

2. Description of Related Art

Along with the continuous development of the integrated circuit (IC) technology, the computer is continuously miniaturized and a data processing speed continues to increase very fast, so that the computers more and more match the use requirement in daily life. Besides, various types of personal computers, such as a desktop PC, a notebook computer, a tablet computer and so on, are derived. In these types of computers, the desktop PC has been widely applied in daily life and changed living habits of human beings significantly.

In the early desktop PC, a peripheral apparatus may be connected with a mother board through an interface card disposed on the mother board. For instance, a speaker is connected with the mother board through a sound card. However, along with the development of technology, the sound card is replaced by a sound chip and integrated into the mother board, and a plurality of audio jacks electrically connected with the sound chip are disposed on the mother board near a rear wall of a housing of the computer. Each of the audio jacks has a plug-in hole and the plug-in holes of the audio jacks can be exposed beyond the rear wall of the housing.

Nevertheless, in order to dispose a heat dissipation device on the rear wall of the housing of the computer, the aforementioned audio jacks have to be moved from the position to another position on the mother board. In particular, when adopting a high level sound chip, the audio jacks are in a great number, so that the plug-in holes of the audio jacks occupy a significantly big area. Under said circumstances, the audio jacks have to be moved to other positions on the mother board to place the heat dissipation device.

### SUMMARY OF THE INVENTION

The present invention is directed to a mother board module, and plug-in holes of audio jacks thereof may have variable positions at a rear wall of a housing of a personal computer host.

The present invention is directed to a personal computer host, and plug-in holes of audio jacks thereof may have variable positions at a rear wall of a housing of the personal computer host.

The present invention provides a mother board module suitable for being disposed in a housing of a personal computer host. The housing has a plurality of expansion port openings at a rear wall of the housing. The mother board module includes a mother board, a sound card and a signal transmission cable. The mother board has a circuit board and a plurality of interface card slots. The interface card slots are juxtaposed on the circuit board and they are disposed corresponding to the expansion port openings respectively. The sound card has a fixing plate and a plurality of audio jacks disposed thereon, and each of the audio jacks has a plug-in hole. The fixing plate is suitable for being removably fixed on one of the expansion port openings, and the expansion port opening exposes the plug-in holes of the audio jacks beyond the rear wall. One end of the signal transmission cable is connected with the sound card while the other end thereof is connected with the circuit board.

The present invention further provides a personal computer host including the aforementioned housing and the aforementioned mother board module. Several embodiments which can simultaneously apply to the aforementioned mother board module and the aforementioned personal computer host are provided below.

In one embodiment of the present invention, the mother board module can further include a first connector and a second connector. The first connector is disposed on the sound card. The second connector is connected with one end of the signal transmission cable for being coupled with the first connector. Either the first connector or the second connector can be a jack, while the other can be a plug and the plug is pluggably disposed in the jack.

In one embodiment of the present invention, the mother board module can further include a third connector and a fourth connector. The third connector is disposed on the circuit board. The fourth connector is connected with the other end of the signal transmission cable for being coupled with the third connector. Either the third connector or the fourth connector can be a jack, while the other can be a plug and the plug is pluggably disposed in the jack. In addition, the circuit board can have an edge area disposed between the expansion port openings and the interface card slots, and the third connector can be disposed in the edge area.

In one embodiment of the present invention, the circuit board can have an edge area disposed between the expansion port openings and the interface card slots, and the other end of the signal transmission cable can be connected to the edge area.

In one embodiment of the present invention, the signal transmission line includes a bus cable.

In the present invention, the sound card with the audio jacks is electrically connected to the mother board by the signal transmission cable and can be selectively fixed to one of the expansion port openings so as to fully utilize the expansion port openings.

In order to make the aforementioned and other features and advantages of the present invention more comprehensible, one embodiment accompanied with figures is described in detail below.

### BRIEF DESCRIPTION OF THE DRAWINGS

FIG. 1A is an exploded view of a mother board module according to one embodiment of the present invention.

FIG. 1B is a perspective view illustrating the mother board module in FIG. 1A applied to a personal computer host.

FIG. 1C illustrates the positions of plug-in holes of audio jacks of the mother board module in FIG. 1B, in which the positions are relative to expansion port openings.

FIG. 2A to FIG. 2C illustrating a sound card in FIG. 1B occupying a space over a different interface card slot and the relative position of the sound card to the interface cards.

### DESCRIPTION OF EMBODIMENTS

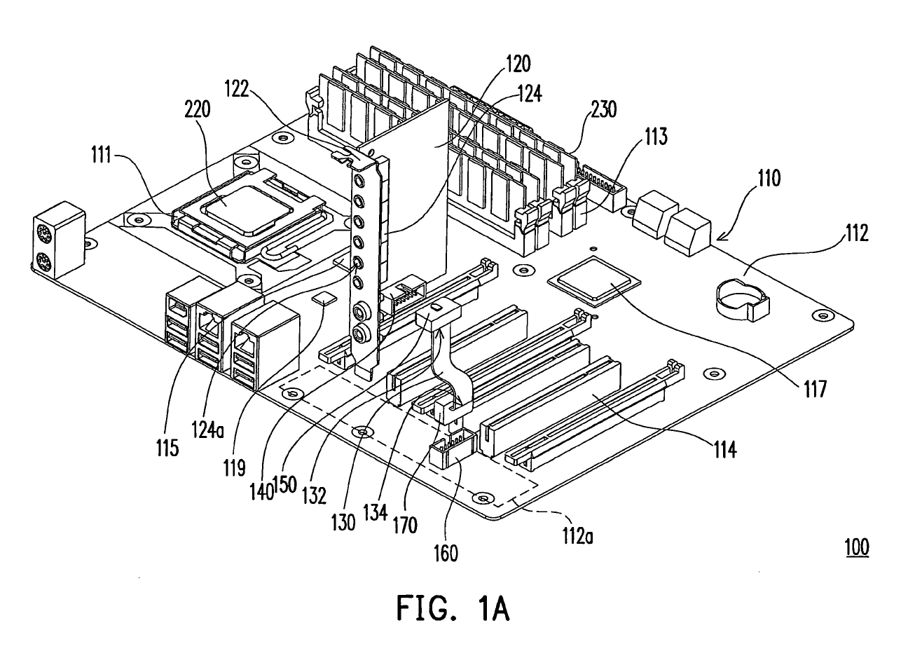

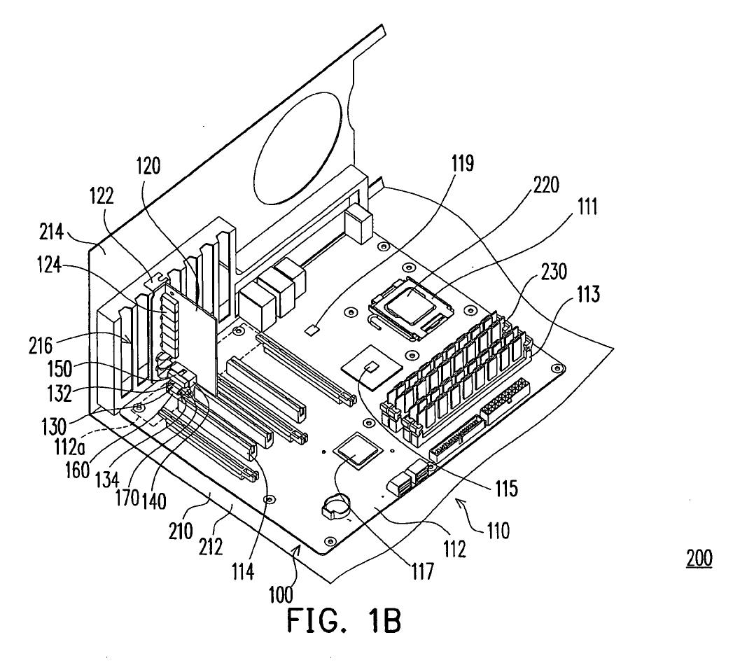

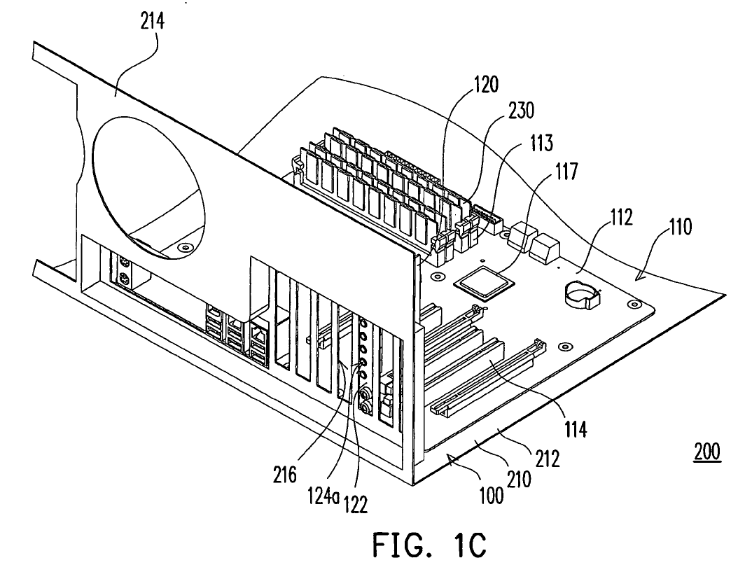

FIG. 1A is an exploded view of a mother board module according to one embodiment of the present invention. FIG. 1B is a perspective view illustrating the mother board module in FIG. 1A applied to a personal computer host. FIG. 1C illustrates the positions of plug-in holes of audio jacks of the mother board module in FIG. 1B, in which the positions are relative to expansion port openings. Referring to FIG. 1A to FIG. 1C, the mother board module 100 of the present invention is suitable for being disposed in a housing 210 of a personal computer host 200. In order to simplify the drawing, FIG. 1B only shows a side wall 212 and a rear wall 214 of the housing 210 as a representation. The housing 210 has a plurality of expansion port openings 216 at the rear wall 214 of the housing 210.

The mother board module 100 includes a mother board 110. The mother board 110 has a circuit board 112 installed at the side wall 212 and a plurality of interface card slots 114. The interface card slots 114 are juxtaposed on the circuit board 112 and are respectively disposed corresponding to the expansion port openings 216. In this embodiment, the specifications of the interface card slots 114 include, for example, PCI, PCI-Express and so forth.

The mother board module 100 further includes a sound card 120. The sound card 120 has a fixing plate 122 and a plurality of audio jacks 124, wherein the audio jacks 124 are disposed on the sound card 120, and each of the audio jacks 124 has a plug-in hole 124a. The fixing plate 122 is suitable for being removably fixed on one of the expansion port openings, and the expansion port opening 216 exposes the plug-in holes 124a of the audio jacks 124 beyond the rear wall 214 (as illustrated in FIG. 1C).

The mother board module 100 further includes a signal transmission cable 130. A first end 132 of the signal transmission cable 130 is connected with the sound card 120 while a second end 134 of the signal transmission cable 130 is connected with the circuit board 112. In this embodiment, the signal transmission cable 130 is, for example, a bus cable.

Moreover, the mother board module 100 can further include a first connector 140 and a second connector 150. The first connector 140 is disposed on the sound card 120. The second connector 150 is connected with the first end 132 of the signal transmission cable 130 for being coupled with the first connector 140. In this embodiment, the first connector 140 is, for example, a jack. The second connector 150 is, for example, a plug. The second connector 150 is pluggably disposed in the first connector 140. However, in another embodiment not shown, the first connector can be a plug and the second connector can be a jack.

Moreover, the mother board module 100 can further include a third connector 160 and a fourth connector 170. The third connector 160 is disposed on the circuit board 112. The fourth connector 170 is connected with the second end 134 of the signal transmission cable 130 for being coupled with the third connector 160. In this embodiment, the third connector 160 is, for example, a jack. The fourth connector 170 is, for example, a plug. The fourth connector 170 is pluggably disposed in the third connector 160. However, in another embodiment not shown, the third connector can be a plug and the fourth connector can be a jack.

The circuit board 112 can have an edge area 112a disposed between the expansion port openings 216 and the interface card slots 114, and the second end 134 of the signal transmission cable 130 can be connected to the edge area 112a. In this embodiment, the third connector 160 can be disposed in the edge area 112a, and the second end 134 of the signal transmission cable 130 can be connected to the edge area 112a through the fourth connector 170 and the third connector 160.

In this embodiment, the mother board 110 can further include a CPU socket 111 disposed on the circuit board 112, memory module card slots 113, a north bridge chip 115 and a south bridge chip 117. Moreover, the personal computer host 200 can further include a CPU 220 inserted in the CPU socket 111 and memory cards 230 inserted in the memory module card slots 113.

In this embodiment, the mother board 110 can further include a sound chip 119 installed on the circuit board 112. The sound chip 119 can have a basic sound signal processing function and the sound card 120 is used to distribute the plug-in holes 124a of the audio jacks 124 on the rear wall 214 of the housing 210.

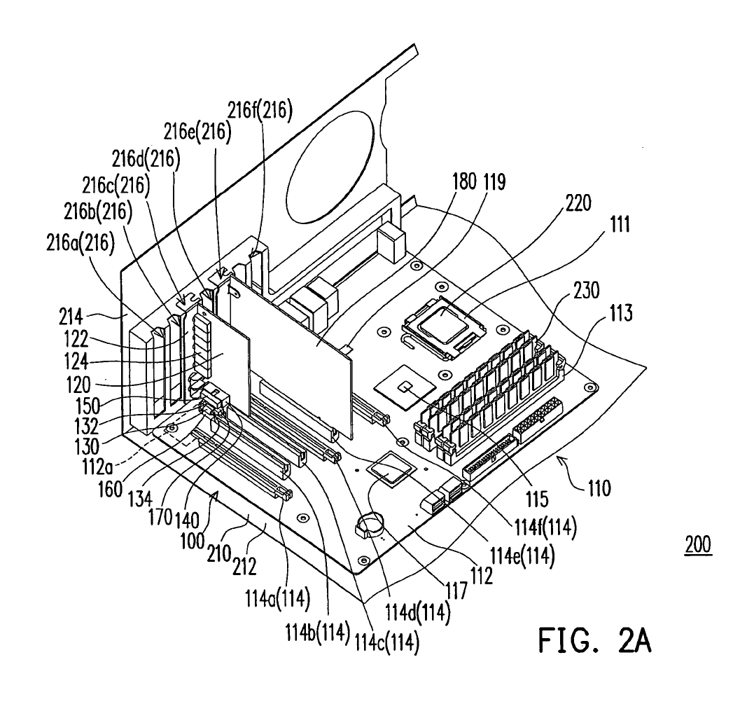

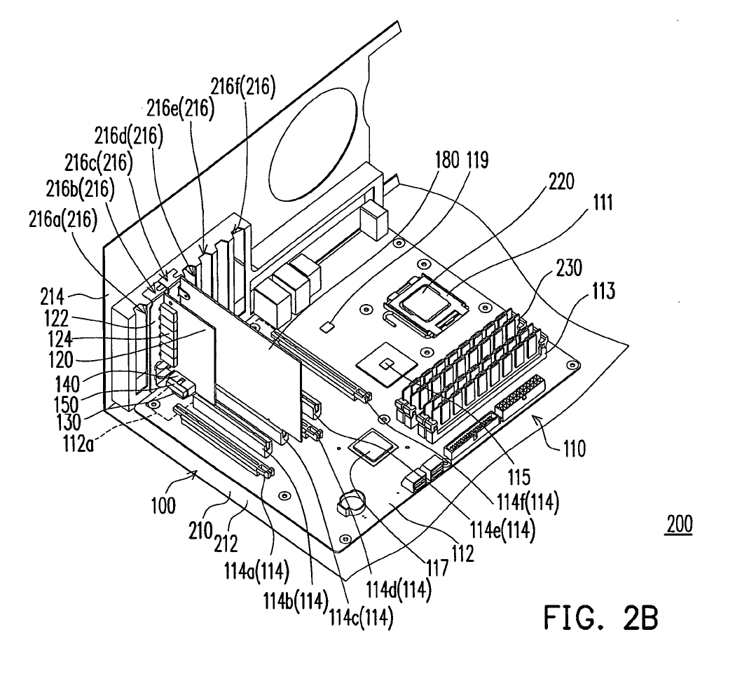

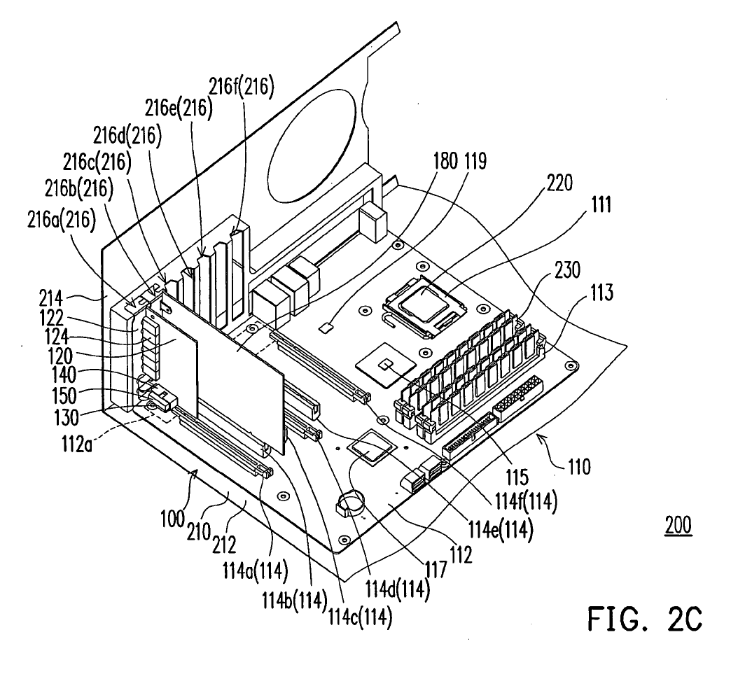

Due to the characteristic that the fixing plate 122 of the sound card 120 can be selectively fixed to one of the expansion port openings 216, the utilization of the interface card slots 114 is significantly flexible and convenient. In order to make the characteristic more comprehensible, the characteristic is further described below accompanied with FIG. 2A to FIG. 2C.

FIG. 2A to FIG. 2C illustrate a sound card in FIG. 1B occupying a space over a different interface card slot and the relative position of the sound card to the interface cards. Referring to FIG. 2A, the mother board module 100 in this embodiment can further include at least one interface card 180 inserted in the interface card slot 114. The interface card 180, such as a network card, a display card or a television card (TV card), is inserted in an interface card slot 114e.

In this embodiment, the interface card slots 114 can include the interface card slots 114a, 114b, 114c, 114d, 114e and 114f, and the expansion port openings 216 which respectively correspond to the aforementioned interface card slots 114 are the expansion port openings 216a, 216b, 216c, 216d, 216e and 216f. When the fixing plate 122 of the sound card 120 is fixed on the expansion port opening 216c, the sound card 120 will occupy the space over the interface card slot 114c and other interface cards cannot be inserted in the interface card slot 114c consequently.

Then, referring to FIG. 2B, when a space arrangement is needed and the interface card 180 has to be inserted in the interface card slot 114c, due to the fact that the signal transmission cable 130 is bendable, the sound card 120 can be moved to other positions flexibly. FIG. 2B exemplifies the sound card 120 fixed to the expansion port opening 216b by the fixing plate 122. Therefore, the sound card 120 will not occupy the space over the interface card slot 114c and the interface card 180 can be inserted in the interface card slot 114c accordingly.

Next, referring to FIG. 2C, when the interface card 180 has to be inserted in the interface card slot 114b, the sound card 120 can be further moved to other positions. FIG. 2C exemplifies the sound card 120 fixed to the expansion port opening 216a by the fixing plate 122.

In summary, in the present invention, the sound card with audio jacks is electrically connected to the mother board by the signal transmission cable and can be selectively fixed on one of the expansion port openings so as to fully utilize the expansion port openings. Hence, the utilization of the interface card slots is significantly flexible and convenient.

Although the invention has been described with reference to a particular embodiment thereof, it will be apparent to one of the ordinary skill in the art that modifications to the described embodiment may be made without departing from the spirit of the invention. Accordingly, the scope of the invention will be defined by the attached claims not by the above detailed description.

What is claimed is:

1. A mother board module suitable for being disposed in a housing of a personal computer host, the housing having a plurality of expansion port openings at a rear wall of the housing, the mother board module including:
a mother board having a circuit board and a plurality of interface card slots juxtaposed on the circuit board, the interface card slots being disposed corresponding to the expansion port openings respectively;
a sound card having a fixing plate and a plurality of audio jacks disposed thereon, each of the audio jacks having a plug-in hole, the fixing plate suitable for being removably fixed on one of the expansion port openings and the expansion port opening exposing the plug-in holes of the audio jacks beyond the rear wall; and
a signal transmission cable, one end of the signal transmission cable being coupled with the sound card while the other end thereof being coupled with the circuit board.

2. The mother board module according to claim 1, further comprising:
a first connector disposed on the sound card; and
a second connector connected with the end of the signal transmission cable for being coupled with the first connector.

3. The mother board module according to claim 2, wherein either the first connector or the second connector is a jack, while the other is a plug, and the plug is pluggably disposed in the jack.

4. The mother board module according to claim 1, further comprising:
a third connector disposed on the circuit board; and
a fourth connector connected with the other end of the signal transmission cable for being coupled with the third connector.

5. The mother board module according to claim 4, wherein either the third connector or the fourth connector is a jack, while the other is a plug, and the plug is pluggably disposed in the jack.

6. The mother board module according to claim 4, wherein the circuit board has an edge area disposed between the expansion port openings and the interface card slots, and the third connector is disposed in the edge area.

7. The mother board module according to claim 1, wherein the circuit board has an edge area disposed between the expansion port openings and the interface card slots, and the other end of the signal transmission cable is connected to the edge area.

8. The mother board module according to claim 1, wherein the signal transmission line includes a bus cable.

9. A personal computer host, comprising:
a housing having a plurality of expansion port openings at a rear wall of the housing;
a mother board module disposed in the housing, the mother board module including:
a mother board having a circuit board and a plurality of interface card slots juxtaposed on the circuit board, the interface card slots being disposed corresponding to the expansion port openings respectively; and
a sound card having a fixing plate and a plurality of audio jacks disposed thereon, each of the audio jacks having a plug-in hole, the fixing plate capable of being removably fixed on one of the expansion port openings, the expansion port opening exposing the plug-in holes of the audio jacks beyond the rear wall; and
a signal transmission cable, one end of the signal transmission cable being coupled with the sound card while the other end thereof being coupled with the circuit board.

10. The personal computer host according to claim 9, wherein the mother board module further includes:
a first connector disposed on the sound card; and
a second connector connected with the end of the signal transmission cable for being coupled with the first connector.

11. The personal computer host according to claim 10, wherein either the first connector or the second connector is a jack, while the other is a plug, and the plug is pluggably disposed in the jack.

12. The personal computer host according to claim 9, wherein the mother board module further includes:
a third connector disposed on the circuit board; and
a fourth connector connected with the other end of the signal transmission cable for being coupled with the third connector.

13. The personal computer host according to claim 12, wherein either the third connector or the fourth connector is a jack, while the other is a plug, and the plug is pluggably disposed in the jack.

14. The personal computer host according to claim 12, wherein the circuit board has an edge area disposed between the expansion port openings and the interface card slots, and the third connector is disposed in the edge area.

15. The personal computer host according to claim 9, wherein the circuit board has an edge area disposed between the expansion port openings and the interface card slots, and the other end of the signal transmission cable is connected to the edge area.

16. The personal computer host according to claim 9, wherein the signal transmission cable includes a bus cable.
